(19) United States
(12) Patent Application Publication
(10) Pub. No.: US 2010/0090477 A1
(43) Pub. Date: Apr. 15, 2010

(54) Foot-Powered Footwear-Embedded Sensor-Transceiver

(76) Inventors: Joseph A. KEATING, Broomfield, CO (US); Timothy N. Bradow, Littleton, CO (US); Raymond R. Johnson, Denver, CO (US); Prativadi B. Narayan, Broomfield, CO (US)

Correspondence Address: Dewey & LeBoeuf LLP, 1101 New York Avenue, NW, Washington, DC, 20005, US

(21) Appl. No.: 12/575,115

(22) Filed: Oct. 7, 2009

Related U.S. Application Data
(60) Provisional application No. 61/103,756, filed on Oct. 8, 2008.

(51) Int. Cl. F03G 7/08; H04Q 9/00

(52) U.S. Cl. 290/1 R; 340/870.07; 290/50

(57) ABSTRACT

A user-powered apparatus, system, and method of providing a pedestrian with information is disclosed. The present invention harvests energy created by a moving pedestrian and takes the harvested energy and uses it to recharge an energy storage device that is embedded in the same footwear. Also built into the footwear may be a microcontroller and sensor, and a transmitter/receiver mechanism by which signals may be transmitted to and received from a wrist watch, iPod®, cell phone and/or any similar portable device on the pedestrian. The footwear may be capable of receiving signals transmitted by the portable device or GPS satellite. The GPS satellite may provide information about the geographical location of the pedestrian. Since the energy storage device may be flexible, it can survive on footwear that gets flexed a significant amount. The energy harvester may harvest energy from the footsteps of the pedestrian or some other source and recharge the energy storage device so that there is no need to replace the energy storage device that is an integral and inseparable part of the footwear.

### RELATED APPLICATIONS

This application is related to and claims priority under 35 U.S.C. §119 of U.S. Provisional Patent Application Ser. No. 61/103,756, entitled “Foot-Powered Footwear-Embedded Sensor-Transceiver,” filed on Oct. 8, 2008, which is incorporated herein by reference in its entirety.

This application is related to U.S. patent application Ser. No. 11/561,277, entitled “Hybrid Thin-Film Battery,” filed on Nov. 17, 2006, U.S. patent application Ser. No. 11/687,032, entitled “Metal Film Encapsulation,” filed on Mar. 16, 2007, U.S. patent application Ser. No. 11/748,471, entitled “Thin Film Battery on an Integrated Circuit or Circuit Board and Method Thereof,” filed on May 14, 2007, U.S. Patent Application Ser. No. 61/087,927, entitled “Energy Device with Integral Collector Surface for Electromagnetic Energy Harvesting and Method Thereof,” filed on Aug. 11, 2008, and U.S. Patent Application Ser. No. 61/096,415, entitled “Energy Device with Integral Collector Surface for Electromagnetic Energy Harvesting and Method Thereof,” filed on Sep. 12, 2008, which are incorporated herein by reference in their entirety.

### TECHNICAL FIELD AND BACKGROUND OF THE INVENTION

This invention relates to an apparatus, method, and system for communicating data. More particularly, this invention relates to a footwear-implantable device which may be powered by harvesting energy from the use of footwear by a walking or running pedestrian and may be stored and/or converted to communication signals to transmit information.

As electronics have become smaller and more durable, there has been a progression towards incorporating electrical devices into clothing or other accessories capable of being worn on the human body. Some examples of such applications include footwear containing light-emitting diodes, ski and snowboard boot heating devices, jackets with a control panel for cell phone or MP3 players and clothing containing continuous heart-rate monitoring devices.

The current technology requires that the electronics have a source of energy to operate. This energy source is typically a battery, which can be embedded within the electronics and configured for a single use, configured to be replaceable, or configured to be rechargeable. Each of these current options has shortcomings, as the embedded battery may render the associated electronics less useful once the battery is discharged or damaged, replaceable batteries require additional space and material to hold the battery, and an externally rechargeable battery requires additional material for a connecting plug and a battery charger. Each of these options is not ideal, as consumers, particularly athletes, tend to demand equipment and clothing that is lighter and without additional power cords.

Thus, a demand exists to have a wearable electronic device that does not include large batteries and, for example, may be able to generate its own energy.

Certain athletic events require rigorous training which demands that athletes keep track of specific statistics in order to achieve optimal performance. For example, current training manuals for persons wishing to compete in marathons strongly suggest that trainees keep records of, at a minimum, their heart rate, pace, routes taken, distance, time, and the weather conditions through which they train. Through such record keeping, marathon trainees can remain focused on reaching the benchmarks that have been set out for them in order to ensure they achieve their goal race pace.

Thus, a demand exists to have all possible pieces of data relating to the performance of their bodies when training for events such as marathons.

In the case of military personnel, it is important to monitor location, physical conditions, ground conditions, and weather conditions to ensure the safety of troops both in this country and abroad. Military personnel need all information pertinent to their surroundings available on little or no prior notice.

Thus, a demand exists to have all data relevant to military operations easily accessible at all times.

### SUMMARY OF INVENTION

Pedestrians impart energy onto, for example, footwear each time he or she walks, jogs, or runs, which presents an opportunity to harness a small portion of the energy expended by incorporating an energy-harvesting device within, for example, footwear. Depending on the application, the harvested energy may be used instantaneously or stored in a component such as a battery and used at defined time intervals or when requested by a remote device.

It is one object of certain exemplary embodiments of this invention to use an energy-harvester, such as a piezoelectric mechanism, to harvest energy from the footsteps of a footwear-pedestrian and use that energy to recharge a device such as a battery that is located such that it is, for example, an integral and/or inseparable part of the footwear.

The present invention may include, for example, a unique arrangement of a microcontroller, a power management unit, a signal transmitter, a signal receiver, a thin-film battery and an energy-harvester. In some embodiments, the energy-harvester may be a piezoelectric sensor that converts motion/vibration energy into electric energy, wherein the converted energy may be used to recharge a battery, thereby providing power to a signal receiver/transmitter. In another embodiment, the piezoelectric mechanism may perform a dual function as a converter of motion energy to electrical energy and also a pedometer.

Certain embodiments of the present invention are also included in a system having a transmitter for transmitting a message to an external receiver. The system may also have sensors that may be monitored by a microcontroller. Certain signals from the sensor may be processed by the microcontroller and the processed information may be transmitted to a receiver that is located on the pedestrian or remotely, such as along the path of the pedestrian's course or on a satellite.

In another embodiment of the invention, the portable receiving device may process the information received and then send a signal back to the footwear, directing it to take an appropriate action. For example, if the number of steps taken reaches a specified number, the portable device may send a signal to the footwear to become softer or stiffer.

In a different embodiment of the invention, the footwear may transmit a signal to a GPS satellite to determine the geographical location of the footwear-pedestrian. In another embodiment of the invention, the GPS satellite may send a signal back to the footwear to direct the footwear-pedestrian to take a different route or make any other announcement.

For improved performance in this application, also disclosed is a manufacturing process for a thin-film battery having a heat and pressure-resilient separation layer for incorporating the battery cell into a printed circuit board.

### BRIEF DESCRIPTION OF DRAWING

Some features and advantages of the invention are described with reference to the drawing of a certain preferred embodiment, which is intended to illustrate and not to limit the invention.

The accompanying drawings, which are included to provide a further understanding of the invention and are incorporated in and constitute a part of this specification, illustrate exemplary embodiments of the invention that together with the description serve to explain the principles of the invention:

FIG. 1 is a diagram of an embodiment of the present invention showing a pedestrian using the device.

FIG. 2 is a detailed view of an article of footwear having the device embedded according to and embodiment of the present invention.

FIG. 3 is a diagram of an embodiment of the present invention showing the subcomponents of the device.

FIG. 4 is a diagram of an embodiment of the present invention showing the step-by-step construction of the device.

### DETAILED DESCRIPTION OF PREFERRED EMBODIMENTS

It is to be understood that the present invention is not limited to the particular methodology, compounds, materials, manufacturing techniques, uses, and applications described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements, and includes equivalents thereof known to those skilled in the art. Similarly, for another example, a reference to “a step” or “a means” is a reference to one or more steps or means and may include sub-steps or subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices and materials are described although any methods, techniques, devices, or materials similar or equivalent to those described may be used in the practice or testing of the present invention. Structures described herein are to be understood also to refer to functional equivalents of such structures.

All patents and other publications are incorporated herein by reference for the purpose of describing and disclosing, for example, the methodologies described in such publications that might be useful in connection with the present invention. These publications are provided solely for their disclosure prior to the filing date of the present application. Nothing in this regard should be construed as an admission that the inventors are not entitled to antedate such disclosure by virtue of prior invention or for any other reason.

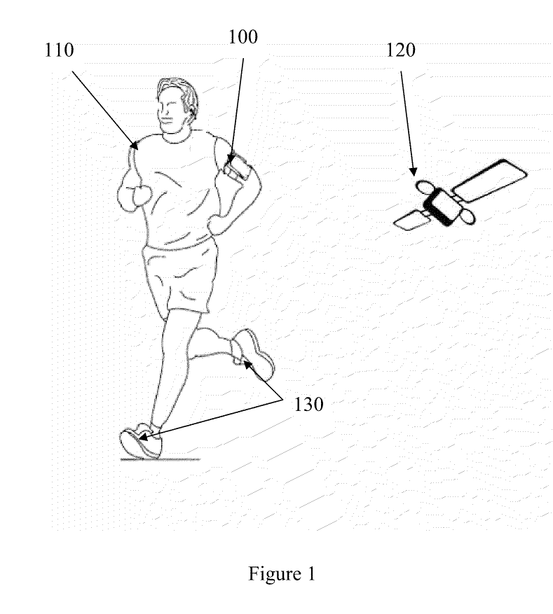

FIG. 1 shows an overall diagram of an embodiment of the present invention. In this diagram, there is a pedestrian 110 with a portable electronic device 100 and a GPS satellite 120. The pedestrian is wearing footwear 130 with the device embedded within. When the pedestrian 110 walks, jogs, runs, or otherwise takes steps, that movement imparts pressure on the shoe that is converted into useful energy. That conversion is performed by an energy-harvesting device located within the footwear 130. The device in the footwear 130 may then, for example, send signals to a portable electronic device 100 which may process the information and store it or send the information back to the footwear 130 so that the footwear 130 itself may perform some action. The pedestrian 110 may be wearing headphones through which the pedestrian 110 may be given any information received by the portable device 100 in the form of audible messages. The device may also receive a signal from a GPS satellite 120 so the geographic location of the pedestrian 110 may be determined, the pedestrian 110 may be instructed to take an alternate route, or the pedestrian 110 may be provided with other relevant information.

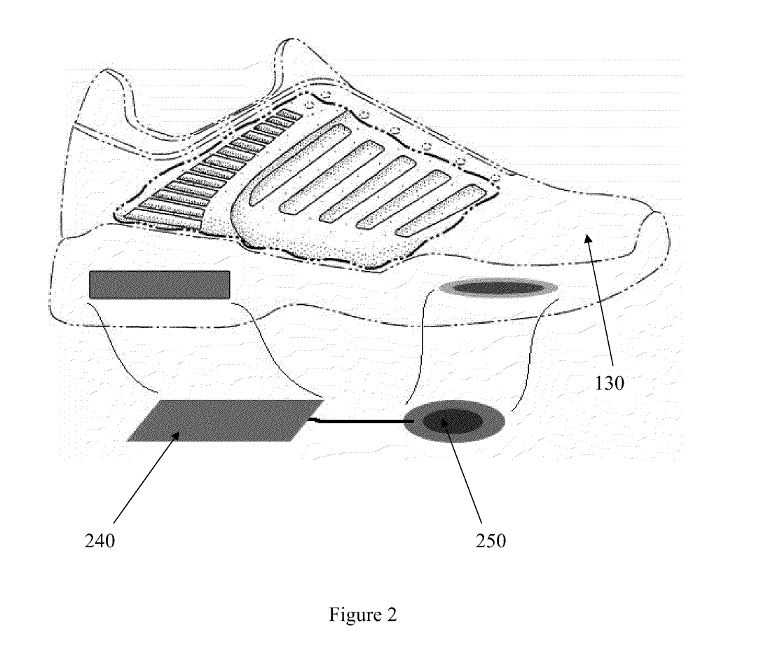

FIG. 2 shows another preferred embodiment of the present invention with footwear 130 containing the embedded circuitry of a microprocessor, an energy-harvesting mechanism 250, a power management unit and an energy storage device 240. Although not shown, some embodiments of the present invention may have a signal transmitter and/or a signal receiver that may potentially be integrated or separately connected to the present invention. When integrated or separately connected, the transmitter may send signals from the footwear device to an external receiver such as a portable electronic device. The receiver may obtain information thereby instructing the footwear 130 or the pedestrian to take some sort of action. When integrated within the device, the receiver may receive signals from one or more GPS satellites so that the pedestrian's geographic location may be determined. In some embodiments, the energy-harvester 250 is a piezoelectric disk, but may also be a radio-frequency transducer, or a device that can convert solar power, wind power, vibration, pedestrian activity such as walking or jogging, water movement, temperature variations or rotational movements into usable energy such as electricity. The energy storage device 240, which may be a thin-film battery, may be used to store the harvested energy such that it can be used at some pre-determined time or when requested by a remote device. In several embodiments, the thin-film battery may contain a metallic lithium anode. In some embodiments, the thin-film battery may not contain a metallic lithium anode at some point during its lifetime but may be a Li-ion or a Li-free thin-film battery.

FIG. 2 shows one particular embodiment where a power management unit and energy storage device 240 are located on the back, heel portion of the footwear 130 and a microprocessor and energy harvesting mechanism 250 are located on the front, toe portion of the footwear 130. The embedded circuitry of the microprocessor, energy harvesting mechanism 250, power management unit and energy storage device 240 may be located in other places on the footwear 130. In some embodiments of the present invention, the power management unit, energy storage device 240, microprocessor and energy harvesting mechanism 250 are incorporated into one module such that they may be placed together as a unit in any location on the footwear 130.

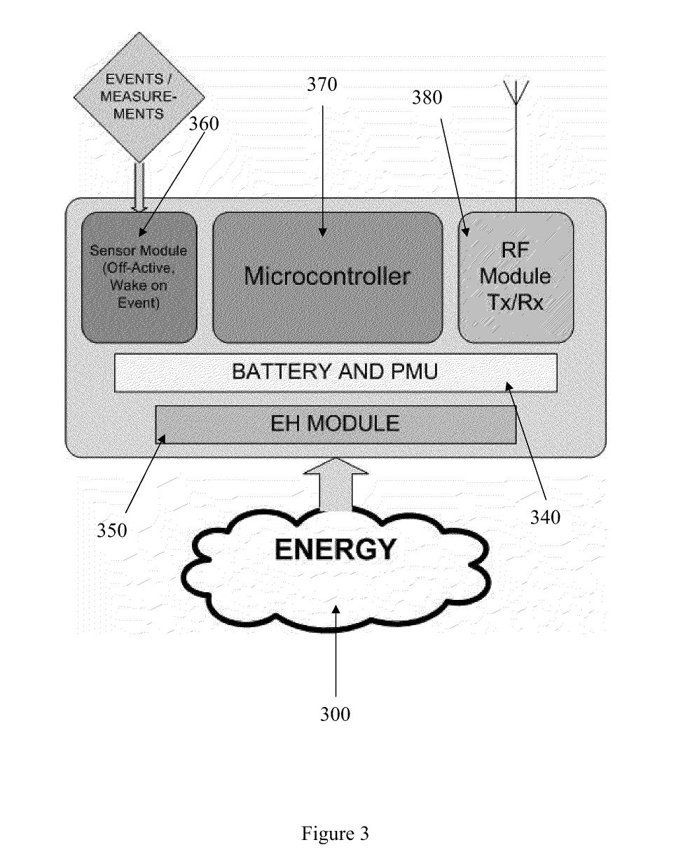

FIG. 3 shows the detailed process occurring within an embodiment of the footwear 130. The mechanical energy 300, resulting from the pedestrian walking with the footwear 130, may be collected by the energy harvesting module 350. The harvested energy then recharges a rechargeable energy storage device 340 under the monitoring and regulation of the power management unit 340 or may be simply stored within the energy storage device 340. The energy storage device 340 may store the energy and, when needed, power the microcontroller 370 and the transmitter and/or receiver 380 depending on whether a signal is being sent out, received or both.

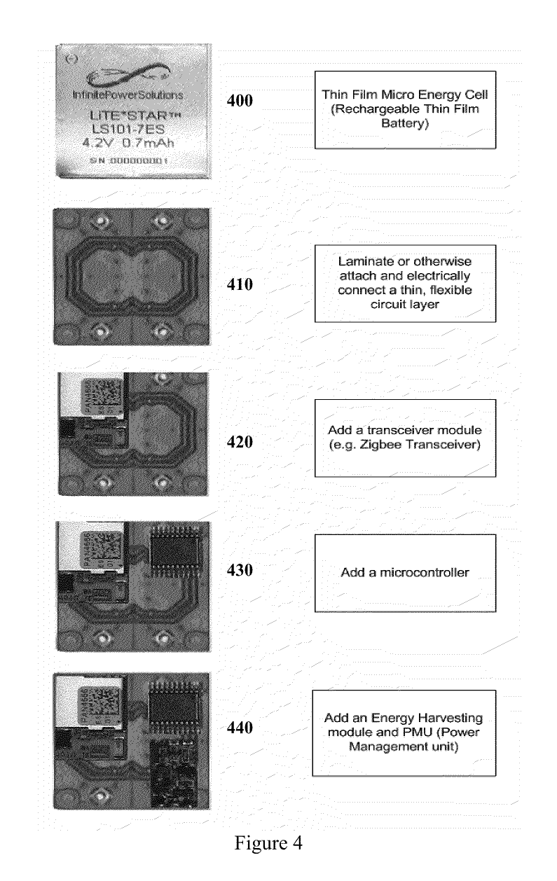

FIG. 4 shows the steps that may be used to construct an embodiment of the present invention on a flexible substrate. Step 400 in this example begins with using an energy storage device, shown as a thin-film battery in the exemplary embodiment, as the centerpiece of construction. Step 410 attaches and electrically connects a flexible substrate to the energy storage device. Step 420 may be to add a transmitter/receiver mechanism to the flexible substrate, followed by the step 430 of placing a microcontroller onto the flexible substrate and the connecting the microcontroller to the transmitter/receiver mechanism. The last step 440 may be to add an energy harvesting mechanism and power management unit to the flexible substrate.

In addition to an electrochemical storage device, such as a battery or thin-film battery, the energy storage component may be an electrical storage device such as a capacitor or thin-film capacitor, but may also be a mechanical energy storage device, such as, for example, a flywheel, micro-flywheel, micro electro-mechanical system (MEMS), or a mechanical spring. The energy storage component may also be an electro-mechanical device, such as a piezoelectric element or a magneto-electric element, similar to the invention disclosed in U.S. Pat. No. 7,088,031, entitled “Method and Apparatus for an Ambient Energy Battery or Capacitor Recharge System” which is herein incorporated by reference in its entirety. The energy storage component may also be a thermal energy storage device, such as a thermal mass container, or it could be a chemical energy storage device, such as, for example, a hydrogen generator with hydrogen container or an ozone generator with ozone container. Each one of these devices may be used to store energy in accordance with one or more exemplary elements of the system. An energy harvester may also be provided, which may include, for example, a device to convert specific types of ambient energy into electrical energy, which may then be stored in an electrochemical storage device such as, for example, a battery or capacitor.

In some embodiments, the system in the footwear contains a sensor 360 that may transmit a signal through the transmitter to a portable device. In some embodiments, the portable device may be a wristwatch but may also be a personal digital assistant or a cell phone. The portable device may also be an iPod®, MP3 player or other digital audio player or a combination of the above and may even receive signals from one or more GPS satellites.

In some embodiments, one or more sensors may measure any number of different physical qualities. In some embodiments, one sensor may be measuring the weather in which case it may be, for example, a thermometer to measure the temperature, a hydrometer to measure the humidity, an anemometer to measure the velocity or pressure of the wind or a barometer to measure the atmospheric pressure. A barometer in combination with a microprocessor may be able to detect changes in pressure and predict changes in the weather and provide a warning to the pedestrian. In several embodiments, one sensor may be used to measure pressure and determine changes in altitude. In some embodiments, one sensor may also measure the speed of a pedestrian, such as, for example, by using an accelerometer.

In some embodiments where the energy storage device is a thin-film battery, the thin-film battery may have a thickness that does not exceed 1 cm and a lateral area that may be less than 10 square inches. In another embodiment, the lateral area of the thin-film battery may be less than 0.25 square centimeters.

In some embodiments, the thin-film battery may have a heat and pressure-resilient separation layer for purposes of incorporating the battery cell into the printed circuit board manufacturing process.

In the several embodiments in which the energy storage device is a rechargeable device, such as, for example, a thin-film battery, this will present an opportunity whereby the present invention may be capable of performing nearly indefinitely. The present invention may allow for energy created through a pedestrian walking or performing any other type of motion to be harvested in an energy harvesting mechanism and for that harvested energy to ensure that the rechargeable energy storage device is so charged.

In some embodiments, the portable electronic device may process the information received and then send a signal back to the footwear to take an appropriate action. An appropriate action could include, for example, the portable electronic device sending a signal to the footwear to become more or less stiff in order to relax the foot after a specified number of steps have been taken.

In some embodiments, the footwear may receive a signal from one or more GPS satellites to determine the geographic location, direction, and speed of the footwear-pedestrian. In another embodiment, in combination with stored maps, the GPS satellite may send back a signal to the footwear to give the footwear-pedestrian an instruction, such as, for example, to take a different route.

This invention has been described herein in several embodiments. It is evident that there are many alternatives and variations that can embrace the performance of ceramics enhanced by the present invention in its various embodiments without departing from the intended spirit and scope thereof. The embodiments described above are exemplary only. One skilled in the art may recognize variations from the embodiments specifically described here, which are intended to be within the scope of this disclosure. As such, the invention is limited only by the following claims. Thus is intended that the present invention cover the modifications of this invention provided they come within the scope of the appended claims and their equivalents.

What is claimed is:

1. An apparatus comprising:
an accessory adapted to be associated with an animal;
an energy harvesting mechanism embedded within said accessory;
an energy storage device connected to said energy-harvesting mechanism;
a power management unit connected to said energy storage device; and
a microprocessor connected to said energy storage device.

2. The apparatus of claim 1, wherein said animal comprises any organism selected from the group of: fish, amphibians, reptiles, birds, mammals, marsupials, primates, rodents, cetaceans.

3. The apparatus of claim 1, wherein said accessory comprises any article selected from the group of: shoe, sandal, slipper, boot, alpine ski, water ski, surf board, snow board, roller skate, inline skate, sled, horse shoe, horse saddle, harness, leash, collar.

4. The apparatus of claim 1, further comprising at least one sensor connected to said microprocessor.

5. The apparatus of claim 1, further comprising at least one signal transmitter connected to said microprocessor.

6. The apparatus of claim 1, further comprising at least one signal receiver connected to said microprocessor.

7. The apparatus of claim 1, wherein said energy-harvesting mechanism comprises any device selected from the group of: piezoelectric transducer, radio-frequency transducer, solar cell, wind turbine, vibration energy scavenger, water movement-to-electric energy converter, rotational movement-to-electric energy converter, and temperature variation-to-electric energy converter.

8. The apparatus of claim 4, wherein said at least one sensor comprises any device selected from the group of: altimeter, pressure gauge, thermometer, barometer, hygrometer, accelerometer, anemometer.

9. The apparatus of claim 1, wherein said energy storage device comprises any device selected from the group of: battery, thin-film battery, capacitor, thin-film capacitor, magneto-electric element, piezoelectric element, thermal mass container, flywheel, micro-flywheel, micro electro-mechanical system (MEMS), mechanical spring, hydrogen generator with hydrogen container, ozone generator with ozone storage container.

10. The apparatus of claim 1, further comprising:
an energy conversion component connected to the energy-harvesting mechanism.

11. The apparatus of claim 1, wherein said energy storage device comprises a thin-film battery with a total thickness that does not exceed 1 centimeter.

12. The apparatus of claim 11, wherein the lateral area of said thin-film battery does not exceed 10 square inches.

13. The apparatus of claim 11, wherein the lateral area of said thin-film battery does not exceed 0.25 square centimeters.

14. The apparatus of claim 11, wherein said thin-film battery contains a heat and pressure-resilient separation layer.

15. The apparatus of claim 11, wherein said thin-film battery contains a metallic lithium anode.

16. The apparatus of claim 11, wherein the electroactive element within said thin-film battery comprises lithium.

17. The apparatus of claim 11, wherein said thin-film battery comprises a lithium-ion battery.

18. The apparatus of claim 11, wherein said thin-film battery comprises a lithium-free battery.

19. The apparatus of claim 5, wherein said signal transmitter transmits a message to a portable device.

20. The apparatus of claim 6, wherein said signal receiver is adapted to receive GPS signals.

21. The apparatus of claim 20, wherein said signal receiver receives a message from a portable device.

22. The apparatus of claim 21, wherein said portable device comprises any device selected from the group of: wristwatch, iPod®, MP3 player, computer, cell phone, and personal digital assistant.

23. A method for communicating information associated with a moving animal comprising:
converting energy into a useful form;
storing said useful form of energy;
powering a processing unit with said stored energy; and
monitoring at least one parameter with at least one sensor.

24. The method of claim 23, further comprising:
communicating monitored parameters to said processing unit;
processing said monitored parameters into user data; and
transmitting said user data.

25. The method of claim 23, further comprising:
receiving GPS signals from one or more GPS satellites;
determining location information from said GPS signals; and
transmitting location information.

26. The method of claim 23, further comprising:
transmitting signals to a portable device.

27. The method of claim 23, further comprising:
receiving signals from a portable device;
processing said signals into user data;
transmitting said user data.
